(19) United States
(12) Patent Application Publication
(10) Pub. No.: US 2012/0146675 A1
(43) Pub. Date: Jun. 14, 2012

(54) TEST DEVICE

(75) Inventors: HONG-MING LAI, Zhonghe City (TW); CHING-FENG HSIEH, Taipei City (TW)

(73) Assignee: ASKEY COMPUTER CORP., TAIPEI (TW)

(21) Appl. No.: 13/012,369

(22) Filed: Jan. 24, 2011

(30) Foreign Application Priority Data
Dec. 14, 2010 (TW) 099143746

(51) Int. Cl. G01R 31/00; G01R 31/20

(52) U.S. Cl. 324/750.16; 324/757.02

(57) ABSTRACT

A test device for testing a circuit board includes a base, a conveying platform, a driving unit, a connecting element, and a testing unit. The base has an operating space from above. The conveying platform is hinged to the base at a variable gradient, communicates with the operating space, and has thereon a carrier movable toward or away from the operating space as needed and configured to carry the circuit board. The driving unit is connected to the conveying platform and configured to drive the carrier to move. The connecting unit is connected to the conveying platform and the driving unit. The gradient of the conveying platform varies when the driving unit drives the carrier to move and thereby moves the connecting unit. The testing unit is movably disposed at the base and has at least one test terminal capable of approaching the operating space and testing the circuit board.

### CROSS-REFERENCE TO RELATED APPLICATION

This non-provisional application claims priority under 35 U.S.C. §119(a) on Patent Application No(s). 099143746 filed in Taiwan, R.O.C. on Dec. 14, 2010, the entire contents of which are hereby incorporated by reference.

### FIELD OF THE INVENTION

The present invention relates to test devices, and more particularly, to a test device for testing a circuit board.

### BACKGROUND OF THE INVENTION

Various circuit boards, such as motherboards, display cards, or network interface cards, are widely used in a wide variety of electronic devices. During a fabrication process of a circuit board, the conforming rate of products has to be put under control in order to meet the requirements of quality control. Hence, a product test is usually conducted in the final stage of a production line to ensure the quality and functionality of a product.

Methods for testing various circuit boards depend on the functions and input/output (I/O) of the circuit boards. For example, a product test conducted on a wireless network interface card entails connecting the wireless network interface card to a test module or an electronic device (such as a host computer) via a bus line, connecting a high-frequency test terminal to a connecting terminal of the wireless network interface card, and testing I/O signals. However, the conventional methods for testing circuit boards require fixing a wireless network interface card in place with a simple jig in order to test the wireless network interface card and manually connecting a high-frequency test terminal to a connecting terminal of the wireless network interface card. Hence, the prior art has its own drawbacks as follows: the pricy high-frequency test terminal is likely to be damaged as a result of unsatisfactory alignment; the connecting terminal or other components might be bent or damaged when subjected to an unduly applied force, thereby incurring costs in a product test; and, to avoid the aforesaid situations, an operation worker has to perform a task of alignment and plugging/unplugging so carefully that the task takes time, and thus the test is time-consuming.

As mentioned above, the convention test methods are likely to damage a test terminal or a circuit board, inconvenient and time-consuming, thereby incurring costs of production unknowingly. Accordingly, it is imperative to provide a test device for testing a circuit board quickly, conveniently, and safely.

### SUMMARY OF THE INVENTION

It is an objective of the present invention to provide a test device for testing a circuit board quickly, conveniently, and safely.

In order to achieve the above and other objectives, the present invention provides a test device for testing a circuit board. The test device comprises: a base having an operating space from above; a conveying platform hinged to the base at a variable gradient and configured to communicate with the operating space, wherein a carrier movable toward or away from the operating space and configured to carry the circuit board is disposed on the conveying platform; a driving unit connected to the conveying platform and configured to drive the carrier to move; a connecting unit connected to the conveying platform and the driving unit, wherein the gradient of the conveying platform varies when the driving unit drives the carrier to move and thereby moves the connecting unit; and a testing unit movably disposed at the base and having at least one test terminal capable of approaching the operating space and testing the circuit board.

The connecting unit further comprises a connecting element connected to the driving unit and a pushing element in movable contact with the connecting element and disposed on the carrier, wherein the connecting element and the pushing element are moved along with the carrier driven by the driving unit.

The connecting unit further comprises a height-adjusting element fixed to the base and a position-limiting pin connected to the connecting element and configured to movably abuts against the height-adjusting element. The connecting element drives the carrier along with the position-limiting pin. The carrier moves to the operating space and drives the position-limiting pin away from the height-adjusting element, thereby switching the conveying platform to a horizontal position. The carrier moves away from the operating space and drives the position-limiting pin to move toward and abut against the height-adjusting element so as to tilt the conveying platform.

The connecting unit further comprises a resilient element connected to the position-limiting pin such that the position-limiting pin is capable of reciprocal motion.

The base has a limiting groove. The conveying platform has a limiting post inserted into the limiting groove and stoppable by an inner wall at two ends of the limiting groove for defining a range of motion (ROM) of the conveying platform. The driving unit comprises a link mechanism. The link mechanism comprises: a handle; a first link connected to and driven by the handle; and a second link having two ends pivotally coupled to the first link and the carrier, respectively, wherein, given a push from the handle, the first link moves the second link, thereby causing the carrier to move to and fro across the operating space.

The driving unit comprises an engaging element. The conveying platform has an engaging member. The carrier is positioned in the operating space upon engagement between the engaging element and the engaging member.

The testing unit comprises: a test platform disposed above the operating space and having the at least a test terminal; and an elevation mechanism connected to the test platform for driving the test platform to move vertically.

The test platform has a plurality of pressing elements for positioning the carrier and the circuit board within the operating space.

The test device of the present invention has advantages described hereunder. The conveying platform lies at a gradient at any moment when the circuit board is being installed or uninstalled, and thus the test device demonstrates ease of use. The test terminal is positioned on the testing unit for inspection and testing and thus protected against any damage otherwise caused to the test device by a human being. With damage being prevented, costs of production are minimized. With the test terminal corresponding in position to a connecting terminal of the circuit board, a test can be conducted on a circuit board using the test device, simply by confining the testing unit to the operating space. Unlike the prior art, the present invention not only prevents the test terminal from coming off the circuit board, but dispenses with the step of aligning the test terminal with the connecting terminal, thereby reducing testing time. The driving unit can be operated to move the carrier for carrying the circuit board and switch the conveying platform to a horizontal position, to allow the carrier to enter the operating space; as a result, the manual operation required for the test procedure is minimized, and the test is semi-automated. Accordingly, the test device of the present invention is convenient, quick, safe, and effective in cutting testing costs.

### BRIEF DESCRIPTION OF THE DRAWINGS

To enable persons skilled in the art to fully understand the objectives, features, and advantages of the present invention, the present invention is hereunder illustrated with specific embodiments in conjunction with the accompanying drawings, in which:

FIG. 1 is a schematic view of a test device according to an embodiment of the present invention;

FIG. 2 through FIG. 4 are schematic views of a test process flow of the test device according to an embodiment of the present invention; and

FIG. 5 is a schematic view of operation of a driving unit and a connecting unit of the test device according to an embodiment of the present invention.

### DETAILED DESCRIPTION OF THE PREFERRED EMBODIMENTS

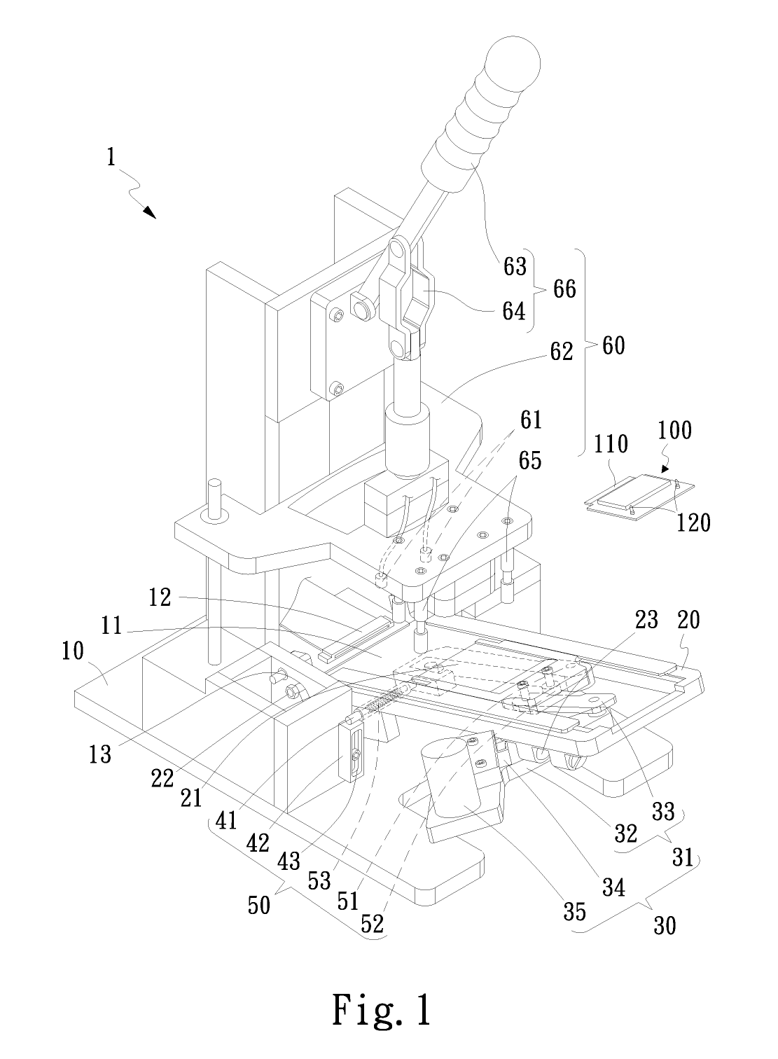

Referring to FIG. 1, there is shown a schematic view of a test device 1 according to an embodiment of the present invention. As shown in the drawing, the test device 1 comprises a base 10, a conveying platform 20, a driving unit 30, a connecting unit 50, and a testing unit 60. The test device 1 is configured to perform a test on a circuit board 100. In this embodiment, the circuit board 100 is a wireless network interface card with a first connector 110 and two connecting terminals 120. The first connector 110 serves as a PCI Express bus interface. The connecting terminals 120 are connected to a receiving antenna of a product after a product test is done.

Referring to FIG. 1, the base 10 has an operating space 11 from above. In this embodiment, a second connector 12 is disposed above the base 10 and connected to the first connector 110 of the circuit board 100. The second connector 12 serves as a PCI Express bus line. The conveying platform 20 is hinged to the base 10 at a variable gradient and configured to communicate with the operating space 11. An operation worker may change the gradient of the conveying platform 20 as needed, while positioning the circuit board 100 or during an operation process. A carrier 21 movable toward or away from the operating space 11 as needed and configured to carry the circuit board 100 is disposed on the conveying platform 20. The driving unit 30 is connected to the conveying platform 20 and configured to drive the carrier 21 to move. The connecting unit 50 is connected to the conveying platform 20 and the driving unit 30. The gradient of the conveying platform 20 varies when the driving unit 30 drives the carrier 21 to move and thereby moves the connecting unit 50. The testing unit 60 is movably disposed at the base 10 and has at least one test terminal 61 capable of approaching the operating space 11 and testing the circuit board 100. To be specific, the test terminal 61 is capable of approaching the operating space 11 and connecting with the connecting terminals 120 of the circuit board 100 in order for a test to be performed on the circuit board 100. The above embodiment should not limit the present invention, as the disclosure of the present invention includes testing the circuit board 100 according to the type of the first connector 110 and the connecting terminals 120 of the circuit board 100 which are connected to the second connector 12 and the test terminal 61 of the test device 1, respectively.

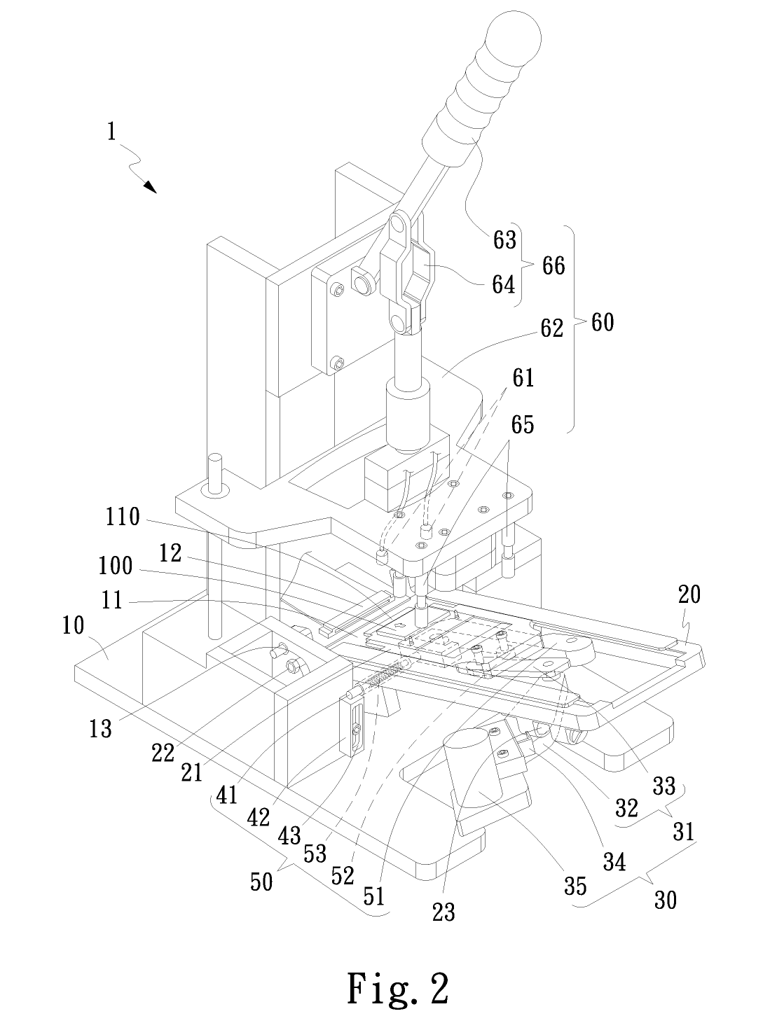

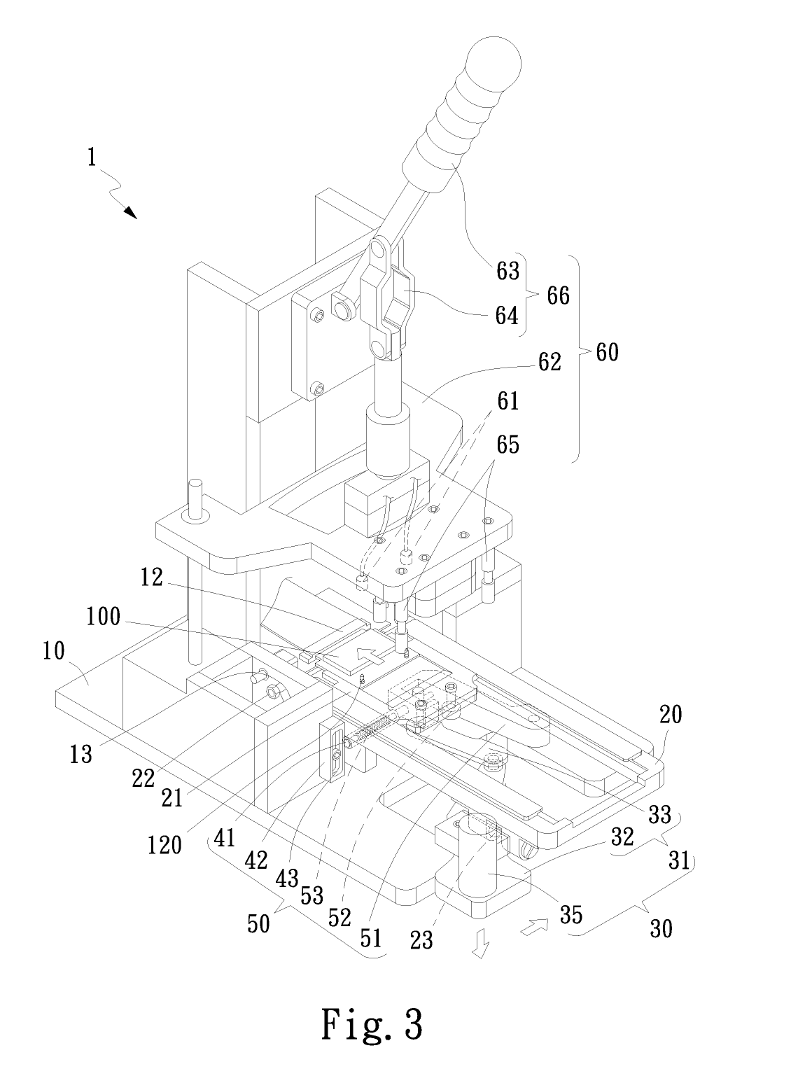

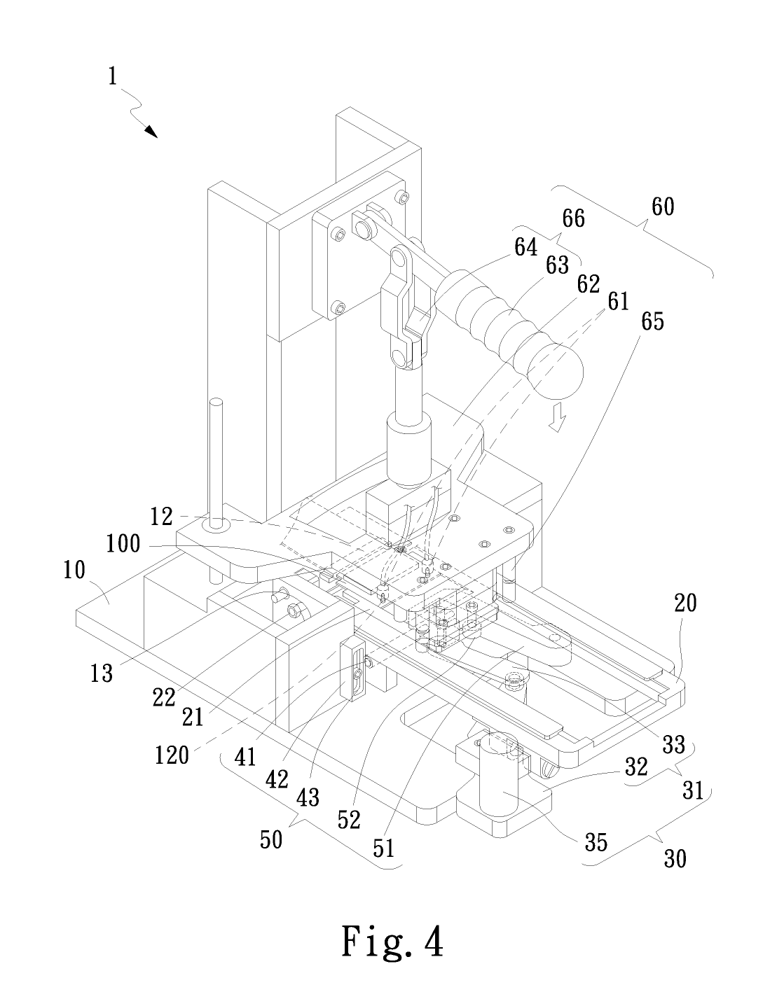

Referring to FIG. 2 through FIG. 4, there are shown schematic views of a test process flow of the test device 1 according to an embodiment of the present invention. As shown in FIG. 2, the circuit board 100 is disposed on the carrier 21 on the conveying platform 20, and the driving unit 30 drives the carrier 21 toward the operating space 11. As shown in FIG. 3, the connecting unit 50 renders the conveying platform 20 horizontal, such that the carrier 21 moves to the operating space 11. As shown in FIG. 4, the first connector 110 and the second connector 12 are connected together, so as for the testing unit 60 to approach the operating space 11 and for the test terminal 61 to connect with the connecting terminals 120 of the circuit board 100. Afterward, a high-frequency signal and power are supplied, lead to the commencement of a test of the input/output (I/O) function of the circuit board 100. Upon completion of the test, the testing unit 60 is removed from the operating space 11 to separate the test terminal 61 from the connecting terminals 120, and then the second connector 12 is separated from the first connector 110, thereby allowing the driving unit 30 to remove the carrier 21 from the operating space 11; meanwhile, the connecting unit 50 tilts the conveying platform 20. Eventually, the carrier 21 returns to the front of the conveying platform 20 thus tilted, thereby allowing the operation worker to take the circuit board 100 out of the carrier 21 to finalize the testing of the circuit board 100.

In this embodiment of the present invention, the connecting unit 50 further comprises a connecting element 51 connected to the driving unit 30 and a pushing element 52 in movable contact with the connecting element 51 and disposed on the carrier 21. The driving unit 30 drives the carrier 21, the connecting element 51, and the pushing element 52 to move concurrently, such that the connecting element 51 and the pushing element 52 are moved along with the carrier 21. In this embodiment, the pushing element 52 is a roller which is rotatably fixed to the carrier 21, moves along with the carrier 21, and is in rotatable contact with the connecting element 51.

The connecting unit 50 further comprises a position-limiting pin 41 connected to the connecting element 51 and a height-adjusting element 42 fixed to the base 10. The conveying platform 20 tilts whenever the position-limiting pin 41 abuts against the height-adjusting element 42. The conveying platform 20 lies horizontally whenever the position-limiting pin 41 separates from the height-adjusting element 42. Upon the commencement of the movement of the carrier 21 toward the operating space 11, the pushing element 22 moves forward along with the carrier 21 to thereby push the connecting element 51 and drive the position-limiting pin 41 away from the height-adjusting element 42, and in consequence the conveying platform 20 is moved downward and lies horizontally. Hence, the driving unit 30 not only moves the carrier 21 but also causes the conveying platform 20 to move downward and lie horizontally. Upon completion of the test, the situation where the carrier 21 has left the operating space 11 and returned to the front of the conveying platform 20 enables the position-limiting pin 41 to move toward and abut against the height-adjusting element 42, and thus the conveying platform 20 tilts again. The operation worker can adjust the gradient of the conveying platform 20 with the height-adjusting element 42 as needed. For example, the height-adjusting element 42 has a slot 43 whereby the base 10 is screwed to the height-adjusting element 42. Furthermore, the gradient of the conveying platform 20 is variable, because the height of the position-limiting pin 41 on which the height-adjusting element 42 abuts can vary according to the position of the slot 43 the base 10 is screwed at.

The connecting unit 50 further comprises a resilient element 53, namely a spring. The resilient element 53 is connected to the position-limiting pin 41 for pushing, on a usual basis, the position-limiting pin 41, such that the position-limiting pin 41 is capable of reciprocal motion. As a result, the position-limiting pin 41 can move along with the carrier 21 to controllably switch the conveying platform between a slanting position and a horizontal position, while the carrier 21 is moving to and fro across the operating space 11. For example, the position-limiting pin 41 abuts against the height-adjusting element 42, and the resilient element 53 is neither compressed nor stretched, whenever the carrier 21 lies in front of the conveying platform 20. During the movement of the carrier 21 toward the operating space 11, the pushing element 52 pushes the connecting element 51 and drives the position-limiting pin 41 away from the height-adjusting element 42, thereby causing the conveying platform 20 to lie horizontally; meanwhile, the resilient element 53 is compressed or stretched and thus is capable of exerting a restoring force. In the situation where the carrier 21 has left the operating space 11 and returned to the front of the conveying platform 20, the resilient element 53 exerts the restoring force upon the position-limiting pin 41, such that the position-limiting pin 41 abuts against the height-adjusting element 42, and in consequence the conveying platform 20 tilts.

The base 10 has a limiting groove 13. The conveying platform 20 has a limiting post 22. The limiting post 22 is inserted into the limiting groove 13 and stoppable by the inner wall at the two ends of the limiting groove 13 for defining the range of motion (ROM) of the conveying platform 20. Hence, the limiting groove 13 and the limiting post 22 together prevents the conveying platform 20 from tilting unduly, prevents the operation worker from exerting a force unduly and thus hitting the testing unit 60, and supports the conveying platform 20 lying at a horizontal position.

In this embodiment of the present invention, the driving unit 30 comprises a link mechanism 31. The link mechanism 31 further comprises a first link 32, a second link 33, and a handle 35. The operation worker holds the handle 35 in operating the driving unit 30. The first link 32 is connected to and driven by the handle 35. The second link 33 has two ends pivotally coupled to the first link 32 and the carrier 21, respectively. Once the operation worker starts to push the handle 35, the first link 32 will move the second link 33, thereby causing the carrier 21 to move to and fro across the operating space 11. Alternatively, the driving unit 30 comes in the form of any other linear transmission mechanism, such as a rail mechanism or a linear gear mechanism, for driving the carrier 21 to perform linear reciprocal motion within the operating space 11; in so doing, the driving unit 30 dispenses with the link mechanism 31.

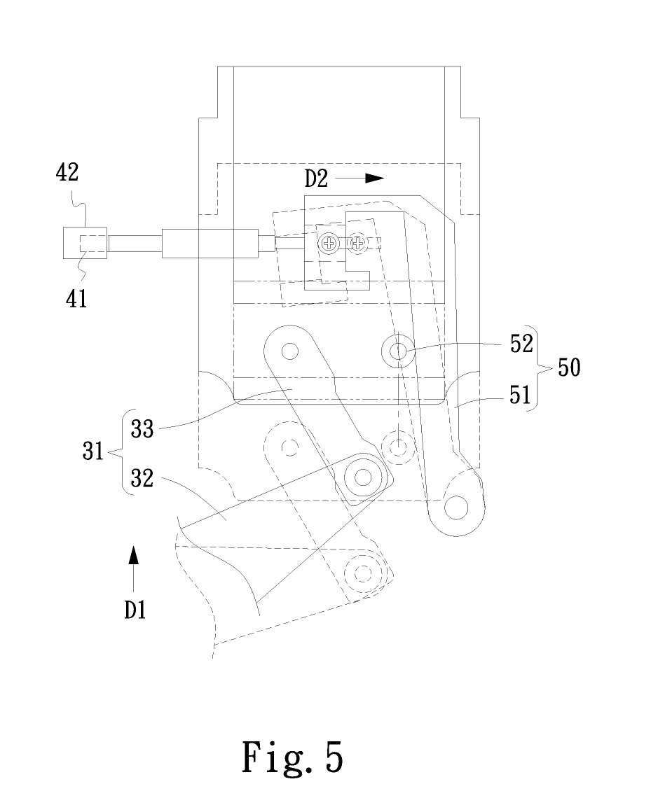

Referring to FIG. 5, there is shown a schematic view of operation of the link mechanism 31 of the driving unit 30 and the connecting element 51 and the pushing element 52 of the connecting unit 50 of the test device 1 according to an embodiment of the present invention. As shown in the drawing, dashed lines depict the state of the link mechanism 31 and the connecting unit 50 when the carrier 21 lies in front of the conveying platform 20 initially, and solid lines depict the state of the link mechanism 31 and the connecting unit 50 when the carrier 21 is moved to the operating space 11 by the link mechanism 31. Once the operation worker pushes the handle 35 of the link mechanism 31, the first link 32 will move the second link 33, cause the carrier 21 and the pushing element 52 thereon to move in a first direction D1, and cause the connecting element 51 to move. The movement of the connecting element 51 causes the position-limiting pin 41 connected thereto to move in a second direction D2 and therefore separate from the height-adjusting element 42. Hence, a single instance of operation of the driving unit 30 serves two purposes concurrently, namely moving the carrier 21 to the operating space 11, and switching the conveying platform 20 to a horizontal position.

Referring to FIGS. 3 and 4, the driving unit 30 further comprises an engaging element 34 (shown in FIGS. 1 and 2 but not in FIGS. 3 and 4), and the conveying platform 20 has an engaging member 23 (shown in FIG. 1 but not in FIGS. 3 and 4) disposed thereunder. The carrier 21 is positioned in the operating space 11 upon engagement between the engaging element 34 and the engaging member 23. For example, the engaging element 34 can be disposed at one end of the first link 32 of the link mechanism 31, such that the engaging element 34 is engaged with the engaging member 23 as soon as the carrier 21 moves to the operating space 11; with the link mechanism 31 being fixed in place, the carrier 21 is positioned in the operating space 11. Also, it is feasible to keep the resilient element 53 of the connecting unit 50 compressed or stretched and keep the conveying platform 20 at a horizontal position.

In this embodiment, the testing unit 60 comprises two said test terminals 61, a test platform 62, and an elevation mechanism 66. Two said test terminals 61 correspond in position to the connecting terminals 120 of the circuit board 100, respectively, and test the circuit board 100. The test platform 62 is disposed above the operating space 11. The elevation mechanism 66 has an operating rod 63 and is pivotally connected to the test platform 62 via a third link 64 for driving the test platform 62 to move vertically. The operation worker lowers the elevation mechanism 66 so as to move the test platform 62 toward the operating space 11 and connect the test terminals 61 to the connecting terminals 120 of the circuit board 100, respectively. Upon completion of the test, the operation worker lifts the elevation mechanism 66 to elevate the test platform 62 and separate the test terminals 61 from the connecting terminals 120 of the circuit board 100. Furthermore, a plurality of pressing elements 65 are disposed at the test platform 62 and configured to position the carrier 21 and the circuit board 100 within the operating space 11 as soon as the test platform 62 moves to the operating space 11, such that the carrier 21 and the circuit board 100 are fixed in place within the operating space 11 and ready for the test. For example, four said pressing elements 65 are disposed at the test platform 62 in a manner that the conveying platform 20 is pressed by two and the carrier 21 by the other two as soon as the test platform 62 descends, such that the conveying platform 20 and the carrier 21 are fixed in place and ready for the test. The pressing elements 65 are coated with an insulative, cushiony, and soft material, such as rubber.

The foregoing embodiments are provided to illustrate and disclose the technical features of the present invention so as to enable persons skilled in the art to understand the disclosure of the present invention and implement the present invention accordingly, and are not intended to be restrictive of the scope of the present invention. Hence, all equivalent modifications and replacements made to the foregoing embodiments without departing from the spirit embodied in the disclosure of the present invention should fall within the scope of the present invention as set forth in the appended claims. Accordingly, the legal protection for the present invention should be defined by the appended claims.

What is claimed is:

1. A test device for testing a circuit board, the test device comprising:
a base having an operating space from above;
a conveying platform hinged to the base at a variable gradient and configured to communicate with the operating space, wherein a carrier movable toward or away from the operating space and configured to carry the circuit board is disposed on the conveying platform;
a driving unit connected to the conveying platform and configured to drive the carrier to move;
a connecting unit connected to the conveying platform and the driving unit, wherein the gradient of the conveying platform varies when the driving unit drives the carrier to move and thereby moves the connecting unit; and
a testing unit movably disposed at the base and having at least a test terminal capable of approaching the operating space and testing the circuit board.

2. The test device of claim 1, wherein the connecting unit further comprises a connecting element connected to the driving unit and a pushing element in movable contact with the connecting element and disposed on the carrier, wherein the connecting element and the pushing element are movable along with the carrier driven by the driving unit.

3. The test device of claim 2, wherein the connecting unit further comprises a height-adjusting element fixed to the base and a position-limiting pin connected to the connecting element and configured to movably abuts against the height-adjusting element, wherein the connecting element drives the carrier along with the position-limiting pin, wherein the carrier moves to the operating space and drives the position-limiting pin away from the height-adjusting element, thereby switching the conveying platform to a horizontal position, wherein the carrier moves away from the operating space and drives the position-limiting pin to move toward and abut against the height-adjusting element so as to tilt the conveying platform.

4. The test device of claim 3, wherein the connecting unit further comprises a resilient element connected to the position-limiting pin such that the position-limiting pin is capable of reciprocal motion.

5. The test device of claim 1, wherein the base has a limiting groove, and the conveying platform has a limiting post inserted into the limiting groove and stoppable by an inner wall at two ends of the limiting groove for defining a range of motion (ROM) of the conveying platform.

6. The test device of claim 1, wherein the driving unit comprises a link mechanism comprising:
a handle;
a first link connected to and driven by the handle; and
a second link having two ends pivotally coupled to the first link and the carrier, respectively, wherein, given a push from the handle, the first link moves the second link, thereby causing the carrier to move to and fro across the operating space.

7. The test device of claim 2, wherein the driving unit comprises a link mechanism comprising:
a handle;
a first link connected to and driven by the handle; and
a second link having two ends pivotally coupled to the first link and the carrier, respectively, wherein, given a push from the handle, the first link moves the second link, thereby causing the carrier to move to and fro across the operating space.

8. The test device of claim 1, wherein the driving unit further comprises an engaging element, and the conveying platform has an engaging member, such that the carrier is positioned in the operating space upon engagement between the engaging element and the engaging member.

9. The test device of claim 1, wherein the testing unit comprises:
a test platform disposed above the operating space and having the at least a test terminal; and
an elevation mechanism connected to the test platform for driving the test platform to move vertically.

10. The test device of claim 9, wherein a plurality of pressing elements are disposed at the test platform for positioning the carrier and the circuit board within the operating space.
